(19) United States
(12) Patent Application Publication
(10) Pub. No.: US 2026/0068749 A1
(43) Pub. Date: Mar. 5, 2026

(54) SEMICONDUCTOR POWER MODULE AND METHOD FOR MANUFACTURING A SEMICONDUCTOR MODULE

(71) Applicant: Semikron Danfoss GmbH, Flensburg (DE)

(72) Inventors: Jacek RUDZKI, Kiel (DE); Lars PAULSEN, Hollingstedt (DE); Mohammadhadi MAGHSOUDI, Flensburg (DE); Holger BEER, Langballig (DE); Tobias SCHUETZ, Flensburg (DE); Tino FILIPIAK-RESSEL, Kiel (DE)

(21) Appl. No.: 19/318,882

(22) Filed: Sep. 4, 2025

(30) Foreign Application Priority Data
Sep. 5, 2024 (DE) 102024125409.2

(51) Int. Cl. H01L 23/10; H01L 23/31; H01L 23/49

(52) U.S. Cl. CPC H01L 23/10

(57) ABSTRACT

Semiconductor power module includes one or more semiconductors placed on a substrate having a conductive layer, a casing made of molding material encapsulating at least the substrate and the semiconductor, at least one socket with a socket base mounted on the substrate and configured for receiving and holding a pin connector in a basically upright position perpendicular to the substrate by means of a hollow space in the socket shank defining the upright direction, at least one sealing ring arranged around the socket shank and resting on the socket base. The sealing ring is fixedly hold in an elastically deformed state in the upright direction against the socket base by the molding material and seals the socket shank against entrance of molding material into the hollow space during the molding step of the casing such that the hollow space provides for an opening on the outside surface of the casing.

### CROSS-REFERENCE TO RELATED APPLICATION

This application claims foreign priority benefits under 35 U.S. C. § 119 from German Patent Application No. DE102024125409.2, filed Sep. 5, 2024, the content of which is hereby incorporated by reference in its entirety.

### TECHNICAL FIELD

The present invention relates to a semiconductor power module and a method of manufacturing a semiconductor power module.

### BACKGROUND

Framed power modules and molded power modules are known in the field of power electronics. Such semiconductor power modules have semiconductor components such as semiconductor diodes, transistors, thyristors, rectifiers and switches in the form of IGBTs or MOSFETs, for example. These components can utilize silicon-based semiconductors or, increasingly common, wide bandgap semiconductors such as silicon carbide (SiC) or gallium nitride (GaN) based semiconductors. In power modules, it is well known to use load and control pins that protrude from a housing.

For power modules operating at high switching frequencies, particularly when using wide bandgap semiconductor technologies, it is important that the contact pins extend the shortest possible distance when connecting the components and the control electronics or load. However, molded power modules with protruding contact pins are rare because the necessary production steps are difficult to perform.

Such contact pins are attached to the substrate before molding. In order to carry out the molding step or the molding process, it is necessary to attach sealing elements that are firmly or semi-permanently connected to the contact pins. These sealing elements must be attached to the contact pins before the contact pins are attached to the substrate so that they can reliably fulfil their sealing function.

One of the disadvantages of the prior art solutions is that the sealing elements must be connected to the contact pins before the contact pins are attached to the substrate. Accordingly, ultrasonic welding of contact pins is difficult and requires complex tools. Therefore, methods for attaching contact pins to substrates, such as soldering or gluing, are rarely used as they are complex and expensive. If the sealing elements are mounted after the contact pins have been attached (when using the prior art solutions), the sealing elements do not exert any pressure on the pin shaft and the sealing contour of the opening in the upper mold half. This has the undesirable consequence that the molding compound can penetrate into the opening in the upper mold part or upper mold half and lead to an overflow of the molding compound during the molding process and thus to contamination of the mold and/or the contact pin.

In addition, in order to form reliable contact pins and preventing an overflow of the molding compound during a molding process according to the prior art, the manufacturing costs increase and gets less flexible because specific contact pins and specific mold dies are provided.

### SUMMARY

There is therefore a need for a semiconductor power module which does not have the above-mentioned disadvantages of the prior art.

It is therefore an objective of the present invention to provide a method for the improved manufacture of semiconductor power modules, in which a sufficiently tight seal of the opening in the upper mold die or the upper mold half can be produced in order to prevent overflow of molding compound and/or contamination of the contact pin while a flexibility of the contact pin configuration is enhanced without increasing the manufacturing costs. The improved manufacturing process should enable a simple, flexible, robust and cost-effective manufacturing process for semiconductor power modules with high reproducibility. A further aim is to provide a semiconductor power module that can be manufactured without the occurrence of the above-mentioned disadvantages.

The problem of the present invention is solved by a semiconductor power module according to independent claim 1 and by a method according to parallel independent claim 13.

Preferred embodiments are defined in the dependent sub-claims, explained in the following description and illustrated in the accompanying drawings.

The semiconductor power module according to the invention comprises one or more semiconductors placed on a substrate having a conductive layer, a casing made of molding material encapsulating at least the substrate and the semiconductor, at least one socket with a socket base mounted on the substrate and configured for receiving and holding a pin connector in a basically upright position perpendicular to the substrate by means of a hollow space in the socket shank defining the upright direction, and at least one sealing ring arranged around the socket shank and resting on the socket base. The sealing ring is fixedly held in an elastically deformed state in the upright direction against the socket base by the molding material and seals the socket shank against entrance of molding material into the hollow space during the molding step of the casing such that the hollow space provides for an opening on the outside surface of the casing.

The substrate of the power module according to the invention, on which the one or more semiconductors are arranged, can be a direct copper bonding (DCB) substrate, such as a Sic, AIN ceramic or the like. It may be advantageous to use a DCB ceramic due to its good thermal conductivity. As is known in the art, various types of semiconductor devices such as semiconductor diodes, transistors, thyristors or switches can be mounted on such a semiconductor DCB ceramic.

Both the DCB substrate and the semiconductor components can be electrically contacted on the outside of the power module also laterally, i.e. essentially parallel to the main directions of extent of the substrate, by means of electrical contact pins or terminals. According to the invention, at least one further socket extends essentially vertically, i.e. at right angles or at an angle of approximately 90° to the substrate, and is exposed to the outside of the power module or protrudes from the power module with a connection on a side parallel to the substrate. The vertical socket is electrically connected to the substrate or at least to a semiconductor arranged on the substrate. In the further course of the description of the invention, any orientation or shape of a socket is covered by the term vertical socket as long as a connection area of the socket is exposed from the encapsulation compound or the casing of the power module on the top or bottom side of the power module, even if the socket has an S-shape or the like.

The vertical socket can be attached to the substrate via its socket base by soldering, ultrasonic welding, laser welding, gluing, sintering, or press-fitting. In one embodiment, the socket is a press-fit socket that can be inserted into holes in the substrate, such as a printed circuit board (PCB), another example of a DCB substrate according to the invention. In one embodiment, the socket may have holes or threaded holes formed in the socket base to be connected to the substrate by a screw connection to electrically connect the socket and fix it to the substrate.

Preferably, after fixing the perpendicular socket to the substrate or semiconductor, a sealing ring and a washer are attached to the socket shank of the socket so that the sealing ring is elastically deformed when the mold is closed to at least partially surround the one or more semiconductors, the substrate and the socket. A mold usually consists of two mold halves, whereby the substrate, the one or more semiconductors and the socket are initially placed in the first (lower) mold half. In this state, the vertical socket does not protrude with its terminal end beyond the parting plane of the mold. The arrangement of the sealing ring and the washer slightly protrudes beyond the parting plane so that the sealing ring is elastically deformed when the second mold half is placed on (top of) the first mold half in order to seal the cavity at the parting plane. Thereby, the arrangement of the sealing ring and the washer is made such that the sealing ring and the washer are safely held on the socket. In this state, the remaining cavity of the mold die is ready to be filled with molding compound to at least partially surround and encapsulate the substrate, the one or more semiconductors and the socket.

In the area of the end of the socket shank remote from the substrate, the mold may comprise a flat surface, which contacts the sealing ring or the washer and lies flat on the sealing ring or the washer to seal the area above the socket shank. In such a case, the socket shank does not protrude beyond the encapsulating compound. Otherwise, the socket shank would be squeezed or crimped by the mold. However, it is also possible that the socket shank is level with the encapsulating compound so that the mold contacts the socket shank. However, in this case, the contact force needs to be low. Otherwise, the socket shank and/or the circuit board, the semiconductors and/or even the substrate could be damaged or deteriorated.

As the mold seals the area above the socket shank, the molding compound does not reach the top of the socket shank and the end surface of the socket shank is not embedded into the molding compound but is exposed to the outside of the molding compound. Hence, the end surface of socket shank is exposed to the outside after removing the encapsulated power module from the mold. During the manufacturing, the mold is pressed against the washer and a compressive force is exerted by the washer to elastically deform the sealing ring in the direction of the socket axis when the upper mold half is placed on the parting plane of the lower mold half to close the cavity. In this closed state of the mold, molding compound/molding material can be filled into the cavity of the mold while the sealing ring remains deformed according to the invention.

Due to the elastic axial deformation of the sealing ring, restoring forces of the sealing ring cause a good sealing force in the axial direction, with which the washer is pressed against the inner surface of the upper mold half and the sealing ring seals with the underside of the washer and seals with the socket base on the underside, or with a second washer if the socket base does not provide a suitable sealing surface. These elastic restoring forces of the sealing ring must be maintained at least until the molding compound/sealing compound has hardened. As soon as the molding compound has hardened, the washer is surrounded by the molding compound/encapsulation compound and held securely in place. In this state, the hardened molding compound is solid and can no longer flow, i.e. it cannot contaminate the connection end which is the end surface of the socket shank. In addition, the hollow space formed in the socket shank is also exposed to the outside of the molding compound. The hollow space can show a circular, oval, or rectangular cross section.

It is also possible that the upper mold does not comprise a flat surface. In this case, it is only necessary that the lower surface of the upper mold contacts with the washer or the sealing ring, respectively. If such a contact is made, an end surface of the socket shank is protected against a penetration of the molding compound. Furthermore, in such a case, it is possible that the socket shank protrudes from the encapsulating compound. For example, the protruding socket shank could be received in a recess formed in the mold.

According to the invention, the sealing ring is also fixed on the radial outside by the molding compound during the encapsulation of the semiconductor(s), the substrate and the socket. As soon as the molded part has hardened, the washer and the sealing ring can no longer move or expand in the direction of the socket axis. Therefore, the sealing ring is held in its elastically deformed state when the molding compound has hardened.

In one embodiment of the invention, the elastically deformed/compressed sealing ring in the socket axis direction seals with the washer and, on its inner side, also with the socket axis, so that no molding compound can run along the socket axis and penetrate on top of the socket shank when the mold is filled. This means that no molding material can contaminate the end of the vertical socket, in other words, the end surface of the socket shank and the hollow space formed in the socket shank is basically free of molding material. In the compressed/deformed state, the sealing ring is flattened in its axial direction, while it expands in the radial direction. Although the sealing ring in this embodiment also seals with the socket shank due to the radial expansion of the sealing ring, this feature is not essential for the invention, as the sealing contact of the sealing ring in the axial direction on both the top and bottom sides is already sufficient to prevent the penetration of molding compound on to the end surface of the socket shank and the hollow space.

Since the sealing ring is elastically deformed and seals against the socket base, against the washer or against two washers in the case of a sandwiched receptacle, and since the upper washer is pressed down towards the socket shank by closing the second mold half, all radial paths for the penetration of molding compound towards the socket shank are closed in a sealing manner so that no molding compound can reach the socket shank and rise up the socket shank to contaminate the connection end.

In a preferred embodiment, the sealing ring rests on the socket base, requiring only a washer that rests on the sealing ring so that when the mold is closed, the washer is pressed down and elastically deforms the sealing ring against the socket base. If the cross-section of the socket base is smaller than the radial extent of the required support diameter of the sealing ring or even smaller than the opening in the sealing ring, the sealing ring would rest on the substrate or the semiconductor or another component of the power module. Although this is not a preferred embodiment, it is covered by the idea of the invention as this solution could be feasible as long as the substrate or the other components of the power module are not damaged by the force elastically deforming the sealing ring and as long as no short circuit, leakage current, impedance or other parasitic current caused by the direct contact of the sealing ring with the adjacent components occurs.

The skilled person will recognize that, according to the invention, the sealing ring and the washer can also be applied to the socket the other way round, i.e. so that the washer contacts the base of the socket and the sealing ring contacts the lower inner surface of the upper half of the mold. In this embodiment, the upper mold half directly deforms the sealing ring elastically when the mold is closed. In this case, the sealing ring would be visible on the top of the finished power module. In this state, however, the molding material is cured and no contamination of the socket shank by the molding material can occur, so that a power module according to the invention is also obtained.

In a further preferred embodiment of the invention, the sealing ring is sandwiched between two washers to be held securely in the closed mold and further in the power module in a deformed state, thereby sealing with both washers and possibly with the socket shank. This embodiment is favored if the socket base has a too small radial extension or supporting surface that is not suitable for direct sealing with the sealing ring, i.e. if the supporting surface of the socket base is too small to ensure reliable elastic deformation of the sealing ring without damaging the sealing ring or the components of the power module arranged on the substrate or damaging the applied/printed circuitry. If there is a risk of the sealing ring or washer contacting the applied circuitry on the substrate, it is preferred that the lower washer contacting the circuitry and/or socket base is made of an electrically non-conductive material to prevent short circuit, leakage current, impedance, inductance or other parasitic currents.

The sealing ring is preferably made of a natural or synthetic elastomeric or silicone material which is elastically deformable so that the sealing ring is able to maintain a sealing contact against the washer and/or the second mold half due to internal restoring forces, at least during the molding/sealing step by which the substrate, the one or more semiconductors and the socket are at least partially surrounded/encapsulated. Since the sealing ring according to the invention does not need to perform any function other than sealing with the washer(s), the socket base and/or the underside of the upper mold, the sealing ring is preferably a standard part, i.e. a standardized component that can be purchased easily and inexpensively. Since the washer or washers according to the invention do not have to fulfil any other function than to provide axial surfaces that can seal under pressure with another flat surface or with the sealing ring, the washer or washers can also be selected as standardized components that can be purchased. Standardized washers are available in an enormous variety of diameters and thicknesses. Thicker washers are also known as spacer washers or simply spacers. All of these variations of washers can thus be used according to the invention to bridge the gap between the socket base or substrate and the top outside of the power module housing, together with the deformed sealing ring. In other words, the washer(s) should be selected in height such that a length of the package of the sealing ring with one or two washers when placed on the socket base is greater by the amount by which the sealing ring elastically deforms when the two mold halves are joined together. The elastic deformation of the sealing ring should be so great that the restoring forces of the deformed sealing ring are high enough to ensure a good sealing pressure, which is high enough to prevent liquid molding material from penetrating radially between the socket base and the sealing ring or the washer or between the sealing ring and the washer or between the washer and the lower inner surface of the upper mold half.

Furthermore, according to the invention, the at least one washer or both washers are made of metal, plastic, reinforced plastic, ceramic, or elastic material, depending on the economic or technical reasons/requirements, in order to avoid short circuits, leakage current, inductance or other parasitic currents. It is noted that the washers can be electrically conductive or can be electrically isolating and the material can be metallic, organic, inorganic or a combination of these materials.

According to the invention, the cross-section of the socket and the socket shank, which is perpendicular or substantially perpendicular to the substrate, can have any shape, preferably round, oval or rectangular. Corresponding to the cross-section of the socket shank, the sealing ring or the opening in the sealing ring has a suitable shape to surround the socket shank. The washer or washers do not necessarily have to have the same outer or inner shape as the sealing ring, as the sealing ring seals with the washer(s) mainly in the axial direction, i.e. in the direction of the socket axis.

In a further embodiment of the invention, more than one upper contact or one lower contact can be guided outwards by means of a socket which is connected perpendicularly to the substrate to an electrical element of the power module. In all these cases, each socket can be led outwards separately in accordance with the invention, i.e. a sealing ring and at least one washer can be arranged on each socket so that no liquid molding compound runs/flows along the socket and contaminates the connection end of the socket during the encapsulation step of the power module.

In the case where a power module is designed to have a lower contact parallel to an upper contact, the idea according to the invention is applicable in an analogous manner, with the difference that the substrate in the first mold half is pushed into its final vertical position when the second mold half is placed on the parting plane.

In a further embodiment of the power module according to the invention, more than one socket arranged vertically on the substrate can be sealed in accordance with the invention in such a way that their connection ends are not contaminated by the molding compound. Each socket can accommodate a sealing ring and at least one washer separately or a possibly oval sealing ring and at least one washer can surround all socket shanks. This works particularly well when two or more sockets have the same electrical potential and can reduce the number of parts required to assemble the power module. A person skilled in the art will probably use a solution here in which the (possibly oval or rectangular) sealing ring is sandwiched between two (possibly oval or rectangular) washers. The skilled person will also find other ways of reducing the number of parts in order to complete power modules according to the invention with more than one upper or lower contact. All these solutions are therefore covered by the inventive concept.

Furthermore, the socket can be of a press-fit type. This means that the socket provides a press-fit connection to the outside. According to the invention, the socket is exposed to the outside of the encapsulation compound. At this exposed portion of the socket, a press-fit connection is provided. For example, at the exposed portion, the socket includes a recess portion or opening portion, both referred to as the hollow space, along the axial direction of the socket or the socket shank and centered with respect to the axial direction. Hence, a cross section along the axial direction may have a U-shape or may be look like “pi” upside down. The hollow space can have any shape and it is not necessary that the hollow space is aligned with the center axis of the socket. The cross section in the radial direction of this hollow space can be circular, rectangular, oval, or any other shape. Accordingly, a counterpart terminal can be inserted and press-fitted into this hollow space of the socket. The counterpart terminal can have a different shape of the cross section to enhance the press-fitting connection.

Using the socket according to the present invention, a connection to the outside can be made flexible using a press-fitting connection suitable for the respective application. Furthermore, if the socket shank does not protrude the encapsulation compound, the mold die can be the same for different connection schemes. For example, if the socket would protrude outside of the encapsulation compound, the mold die would need a recess for receiving the socket in order to prevent squeezing or crimping of the socket when the two molding dies are contacted. However, the molding die according to one embodiment of the present invention can have the flat surface. Hence, different arrangements of the socket can be implemented while still using the same molding die. This results in reduced manufacturing costs because the manufacturing of the power modules does not require individual molding dies.

Furthermore a flat surface allows for a better stacking and packaging of power modules as damaging of protruding connectors at least on one surface is prevented. This applies for transportation as well as for use of a plurality of power module arranged in a stack. Possibly interconnection of two power modules can effected by using pins with two press-fit terminals, e.g.

In addition, the configuration of the socket can be easily changed and varied throughout different power modules. This enhances the flexibility and individuality for the manufacturer and the costumer also. Also, specific terminals can be provided without reducing the reliability during the manufacturing.

It is noted that the power modules are connected to a system of a higher level by connecting the power module terminals exposed to the outside. The prior art and the present invention differ in that the prior art provides at least one protruding terminal and the present invention provides at least one press-fitting terminal. Using the press-fitting terminal enables that a press-fitting pin or a contact pin of the press-fit pin type of construction can be inserted into the hollow space of the socket after the molding process so that a protruding terminal is formed. As a result, the press-fitting terminal is changed to the protruding terminal after the molding process so that the costumer receives a power module having the same terminals as in the prior art.

Furthermore, the present invention provides a method for manufacturing a semiconductor power module having one or more semiconductors placed on a substrate having a conductive layer, wherein the substrate and the semiconductors are covered at least partially by a casing formed of a molding material, wherein at least one opening in the casing is provide for electrically contacting the conductive layer. The method comprising the steps of providing a substrate having a conductive layer and one or more semiconductors placed on it, fixing on the conductive layer at least one socket with a socket base such that a socket shank extends perpendicularly to the substrate, placing a sealing ring over the socket shank such that the sealing ring rests on the socket base, placing the substrate with the socket and the sealing ring in a first mold half, closing the first mold half in a upright direction parallel to the socket shank by means of a second mold half, thereby elastically deforming the sealing ring by pressing it onto the socket base by means of the second mold half such that the second mold half closes an hollow space of the socket, wherein the sealing ring seals the socket shank against entrance of molding material into the hollow space, filling the cavity of the mold with molding material, opening the mold after curing of the molding material, and removing the semiconductor power module from the mold.

### BRIEF DESCRIPTION OF THE DRAWINGS

With reference to the attached Figs., preferred embodiments of a power module according to the invention are explained in more detail in order to improve the understanding of the basic idea of the invention. The present embodiments do not limit the scope of the inventive concept, but merely represent possible alternative embodiments to which modifications can be made within the knowledge of a person skilled in the relevant field without departing from the scope of the invention. Therefore, all such modifications and changes are covered by the claimed invention. It is shown in the Figs.:

FIG. 1 a first embodiment of the power module according to the invention before the molding die is closed;

FIG. 2 the power module from FIG. 1 with the molding die closed;

FIG. 3 the power module from FIG. 1 after removal from the molding die;

FIG. 4 a second embodiment of the power module according to the invention;

FIG. 5 a third embodiment of the power module according to the invention;

FIG. 6 a fourth embodiment of the power module according to the invention;

FIG. 7 a fifth embodiment of the power module according to the invention;

FIGS. 8a & 8b a possible embodiment for the socket and cross sections of the socket and a corresponding contact pin;

FIGS. 9a & 9b a possible embodiment for the socket;

FIG. 10 a power module where a contact pin is assembled in a socket; and

FIG. 11 a schematic flow chart for a method for manufacturing a power module according to the invention.

### DETAILED DESCRIPTION

For a better traceability and for sake of improving the legibility of the detailed description same reference numbers are used throughout the Figs. for indicating equal parts or elements having the same function.

Even though indications are given for the upper and lower directions and locations, they refer only to the orientation of the elements as shown in the Figs. and must not coincide with the orientations and locations in the normal usage of a power module according to the invention. So, e.g., a top contact shown in the Figs. might be oriented to the bottom or sidewards in the normal usage of the power module according to the invention. The indications concerning the top or the bottom are used merely to enhance the understanding and legibility of the Figs. and their description and are derived from the usual positioning of the encapsulation mold and the used mold halves.

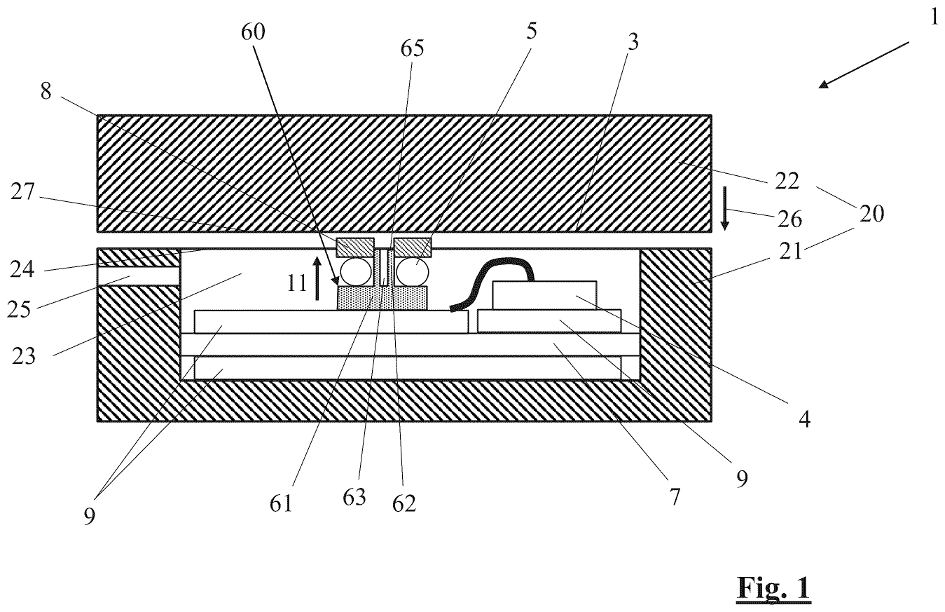

FIG. 1 shows a first embodiment of a non-encapsulated semiconductor power module 1 (also referred to as a power module 1) according to the invention placed in an open molding die or an open encapsulation mold 20, i.e. the situation right before closing the encapsulation mold 20 to perform the encapsulation step with which at least partially a substrate 7 with a bonded or conductive layer 9 applied thereon, one or more semiconductors 4 connected to the bonded/conductive layer 9, and a socket 60 protruding basically perpendicular to the substrate 7 are encapsulated with molding compound; also called encapsulation compound or molding material. The perpendicular socket 60 is fixed via a socket base 61, e.g., on the conductive layer 9 by any known fixing process, such as soldering, ultrasonic welding, laser welding, bonding, sintering or by press-fit. It is also covered by the invention that the socket 60 is located and fixed with its socket base 61 to any other component arranged in the power module 1, e.g. a socket 60 bonded to the semiconductor 4 via its socket base 61.

Further to the invention and the exemplary embodiment shown with FIG. 1, after a socket 60 is fixed to the substrate, the bonded or conductive layer 9 or to the semiconductor 4, a washer 8 and a sealing ring 5 are received by the socket shank 62 of the socket 60 in that way that the sealing ring 5 contacts the socket base 61. This (pre-)assembly group consisting of substrate 7 with the bonded or conductive layer 9, the semiconductor 4 and the socket 60 with the washer 8 and the sealing ring 5, is placed in a first, lower mold half 21 such that the socket shank 62 with its socket shank end 65 is oriented upright.

The socket shank 62 is a protrusion from the socket base 61 and includes a hollow space 63 along the socket shank axis 64. A cross section along the axial direction of the socket shank 62 shows two parallel protrusions sandwiching a free space. The free space is the hollow space 63 which can have a 3D tubular shape. The hollow space 63 is recessed from the socket shank end 65 towards the socket base 61. The direction to the socket base 62 is a downward direction and a direction opposite to the downward direction is an upward direction 11. Hence, the hollow space 63 is formed from the socket base 61 in the upward direction 11. The hollow space 63 can completely or partially pass the socket shank 62. In a cross section in the radial direction of the socket shank 62, the hollow space 63 can have any shape and can be circular, rectangular, or oval. The hollow space 63 can be aligned to the center axis of the socket shank 62 but this is not necessary. The hollow space 63 is exposed to the outside of a casing 15 after the molding process of the casing 15. Therefore, the hollow space 63 forms an opening on the outside of the casing 15.

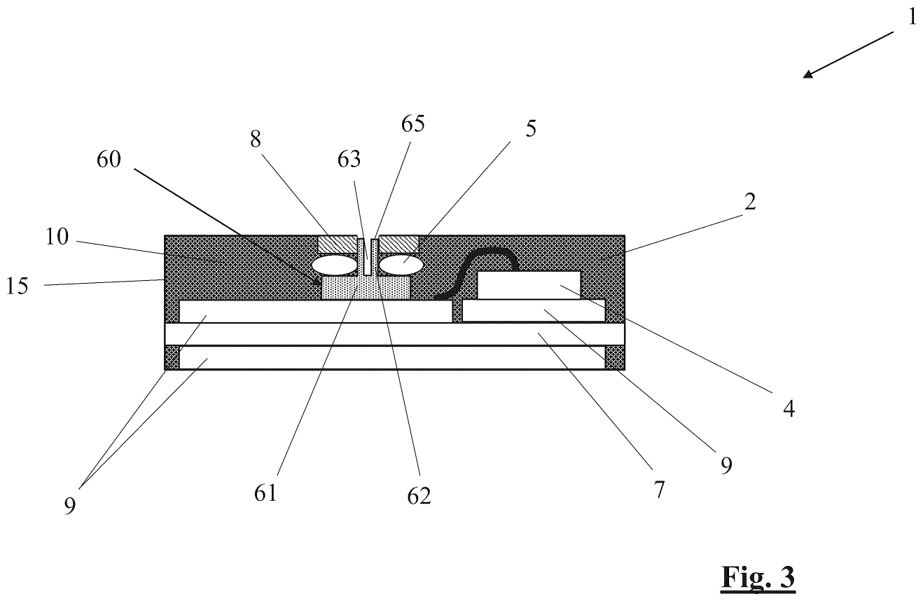

As can be seen in FIG. 1, the first, lower mold half 21 comprises at the upper end a mold separation line or a parting plane 24 at which the first, lower mold half and the second, upper mold half 22 can be joined together in order to tightly close a cavity 23 of the mold 20. When the mold 20 is closed encapsulation or molding material 10 (see FIG. 3) can be filled in the cavity 23 via a mold inlet 25. After curing of the encapsulation material 10 the finished power module 1 can be removed from the lower mold half 21 after the second, upper mold half 22 is taken away. FIG. 3 shows the power module according to FIGS. 1 & 2 after removing from the encapsulation mold 20 wherein the encapsulation compound or encapsulating material 10 forms a casing 15 of the power module 1. Hence, the casing 15 also corresponds to an encapsulation of the power module 1. However, it is possible that a housing is provided additionally to the casing 15.

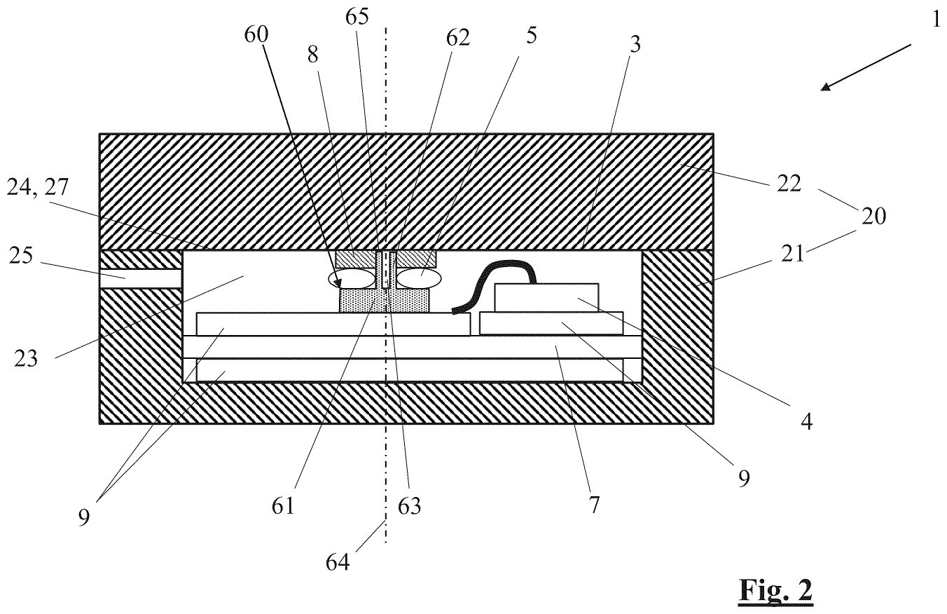

It can be seen further from FIG. 1 that in the open state of the encapsulation mold 20 the socket shank end 65 of the socket 60 does not protrude in vertical direction over the parting plane 24, wherein at least part of the washer 8—received on the socket shank 62 and supported by the sealing ring 5—protrudes in vertical direction over the parting plane 24, and wherein the sealing ring 5 is in an undeformed state, in which the cross section of the sealing ring 5 shows a round, basically circular form. According to the invention the upper mold half 22 comprises a generally flat surface 3 in the face showing towards the cavity 23, which is configured to contact at least the part of the washer 8 protruding the parting plane 24 when the second, upper mold half 22 is placed in direct contact on the first, lower mold half 21, i.e. when the encapsulation mold 20 is closed and prepared for the encapsulation step (see also FIG. 2).

When the second, upper mold half 22—as shown by the arrow 26 in FIG. 1—is placed on the lower mold half 21, the washer 8 is pushed downwards along the socket shank 62 axis, i.e. the socket shank 62 longitudinal direction, into the cavity 23 of the mold 20, whereby, according to the invention, the sealing ring 5 resting stationary on the socket base 61 is deformed elastically in axial direction or an upright direction and expands radially. In this state the sealing ring 5 shows a more or less oval cross section as can be seen in FIG. 2. FIG. 2 shows the final deformed state of the sealing ring 5 in the (fully) closed encapsulation mold 20. At this point, according to the invention, the cavity 23 of the mold 20 can be filled with encapsulation material 10 via the mold inlet 25 to encapsulate at least partially the substrate 7, the one or more semiconductors 4, and the perpendicular socket 60 together with the elastically deformed sealing ring 5 and the non-deformed washer 8.

In the situation as shown with FIG. 2, the sealing ring 5 is forced to an elastically deformed state in the direction of a socket shank axis 64, whereby the elastic reaction forces of the sealing ring material provide sealing forces in axial direction of the sealing ring 5 upwards onto the washer 8 and downwards onto the socket base 61. The washer 8 is pushed upwards by means of the elastic restoring forces of the deformed sealing ring 5, and is pressed against the lower mold surface, the cavity limiting surface 27 of the second upper mold half 22. This upwards directed elastic force causes a sealing effect of the washer 8 with the cavity limiting surface 27 in order to prevent that molding material 10 can flow during the molding step towards the socket shank 62 or the upper end surface of the socket shank 62. Such an unwanted material flow would result in a contamination of the socket shank end 65 of the socket 60. Due to the elastically restoring forces of the sealing ring 5 in axial direction, i.e. in socket shank 62 direction, this access, and all other possible accesses for molding material 10 in radial direction to reach the socket shank 62 and climb-up the socket shank 62, are sealed actively by elastic restoring forces of the deformed sealing ring 5. By means of these elastic restoring forces sealed contacts of the washer 8 and the mold 20, of the washer 8 and the sealing ring 5, of the sealing ring 5 and the socket base 61 at least in the axial/vertical directions are provided.

In the first exemplary embodiment as shown with FIGS. 1 to 3, the sealing ring 5 is deformed elastically such that the cross section of the sealing ring 5 is formed oval due to the compression in axial direction and is expanded in the radial directions (away and towards the socket shank 62). This expansion effect towards the socket shank 62 can be used to achieve a further sealing contact of the deformed sealing ring 5 with the socket shank 62. However, as described above the axial oriented sealings are regularly sufficient to prevent that fluid molding material flows towards the socket shank 62 and upwards along the socket shank 62 to contaminate the socket shank end 65 during the molding step.

FIG. 3 shows an encapsulated power module 1 according to the invention with a top contact, i.e. the socket shank end 65 with the hollows space 63 free of encapsulation material 10 and encapsulated by the encapsulation material 10 which forms the casing 15 of the power module 1. The shown power module 1 can be contacted at a side basically parallel to the substrate 7. The electrical connections can be made by inserting a contact pin 70 into the hollow space 3 and/or connecting a contact pin 70 on the end surface of the socket shank 62. As a person skilled in the relevant art derives, this can be in use of the power module any side of the power module and must not be the top side as shown with FIG. 3. A person skilled in the relevant art also will be aware that the shown embodiment for a power module will have at least one or more other contact terminals which, e.g. protrude in direction of the plane of the substrate 7, which would be in FIG. 3 in lateral direction. In this regard the embodiment shown with FIGS. 1 to 3 only show a simplified embodiment in order to illustrate the underlying idea of the invention.

As can be seen in FIGS. 1 to 3, the power module 1 according to the present invention can be manufactured using one type of a molding die. However, as can be recognized from the Figs., the same molding die can be used if the socket 60 is placed at a different location because the socket 60 does not protrude over the parting plane 24. The electrical connection to the outside of the power module is made through the hollow space 63 in the socket shank 62. Therefore, manufacturing costs are reduced because the molding die can be used for several configurations of the socket 60.

It is noted that if the socket 60 crosses the parting plane 24 the present invention is still feasible, although, in such cases, the molding die has to be changed for different configurations. Also in such a case, a contact pin 70 can be connected to the socket 60 by inserting the contact pin 70 into the hollow space 63.

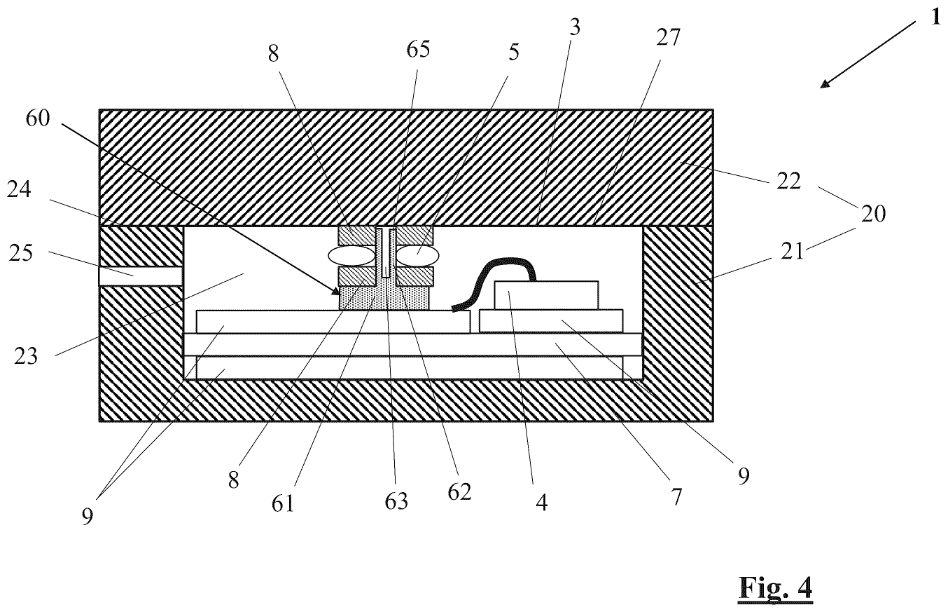

In FIG. 4 another implementation of idea according to the invention is shown. The embodiment of a power module 1 of FIG. 4 deviates from the embodiment shown with FIGS. 1 to 3 in that the sealing ring 5 is sandwiched between two washers 8. This possibility is preferred in particular when the socket base 61 support surface for supporting the sealing ring 5 when being deformed by closing the mold 20, is not big enough to ensure a proper deformation of the sealing ring 5, as therewith non-sufficient high elastic restoring forces are achieved to provide sealed contacts in radial direction in order that no encapsulation material can enter between the cavity limiting surface 27, the washer 8, the sealing ring 5 and the socket base 61. As can be seen from FIG. 2, the sealing ring 5 would slip over the socket base 61 when pushed downwards if the second lower washer 8 would not be present. Hence, the height of the socket base 61 would limit the elastic deformation of the sealing ring 5 and the restoring forces to ensure good sealing conditions between the cavity limiting surface 27, the washer 8, the sealing ring 5 and the socket base 61. Therefore, a second, lower washer 8 is provided to rest on the socket base 61 and provides support against the deformation of the sealing ring 5 when the encapsulation mold is closed for performing the encapsulation step.

Hence, the solution shown with the embodiment of FIG. 4 is particularly preferred when the radial extension of the socket base 61 is small or a press-fit pin is used, e.g. A person skilled in the relevant art will derive from FIG. 4 that washers covering or surrounding the socket base, e.g. in form of a sleeve or the like, and providing a support surface for the sealing ring 5 are also covered by the scope of the invention, even not shown in the Figs. It is further covered by the invention that the washers 8, independent from the illustrated embodiments, can comprise a circumferential sealing groove—like the known sealing grooves in the art—at least on that side which faces the sealing ring 5. The invention also covers the use of three or more washers, for instance for adapting the height of the washer/sealing ring-package to the height of the socket shank. In this context it is also imaginable to use two sealing rings 5 and three washers 8 placed alternately one above the other such that each sealing ring 5 is sandwiched between two washers 8. Here a person skilled in the relevant art will find a lot of possibilities to come to a package filling the space between the socket base 61 and the socket shank end 65 of the socket 60 such that at least one sealing ring 5 is elastically deformed when the encapsulation mold 20 is closed. As all these embodiments of the invention are within the range of the knowledge of a person skilled in the relevant art it is refrained from the illustration of these possibilities.

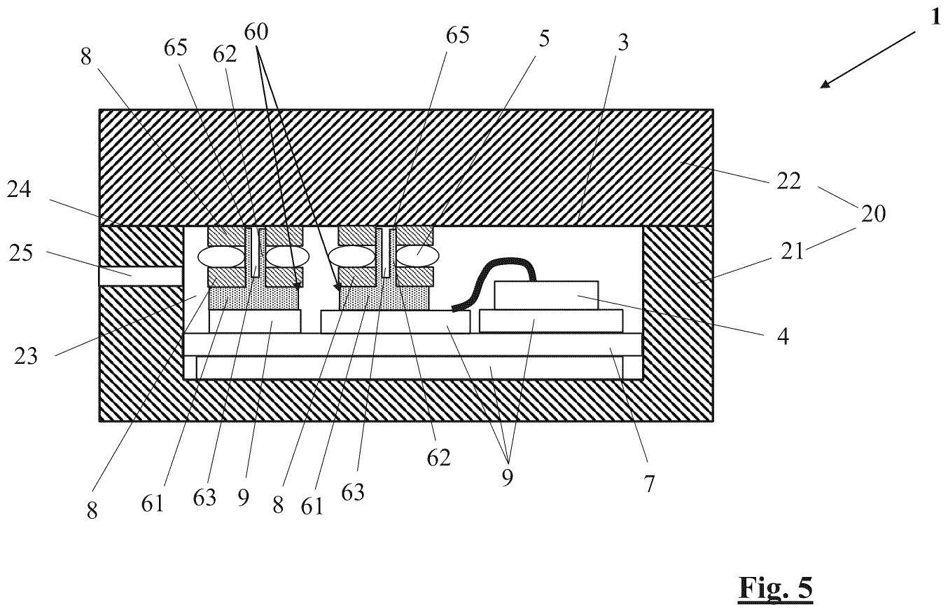

A further embodiment of the invention is shown with FIG. 5 from which it can be derived that the invention also covers power modules 1 having more than one socket 60 protruding basically perpendicular to the substrate 7. In the embodiment of FIG. 5 an embodiment with two sockets 60 is shown as an embodiment representing all power modules 1 according to the invention with more than one socket 60 protruding perpendicular to the substrate 7. A person skilled in the relevant art will detect that it is merely a question of design to arrange and fix two or even more perpendicular sockets 60 on a substrate 7 or on the one or more semiconductors 4. In accordance with the number of perpendicular sockets 60 the upper mold half 22 still has a flat surface if all sockets 60 do not protrude the encapsulating mold's parting plane 24. In the other case the upper mold half 22 must have a recess for each socket 60 protruding the parting plane 24 at a corresponding location such that these sockets 60 are not damaged when closing the mold.

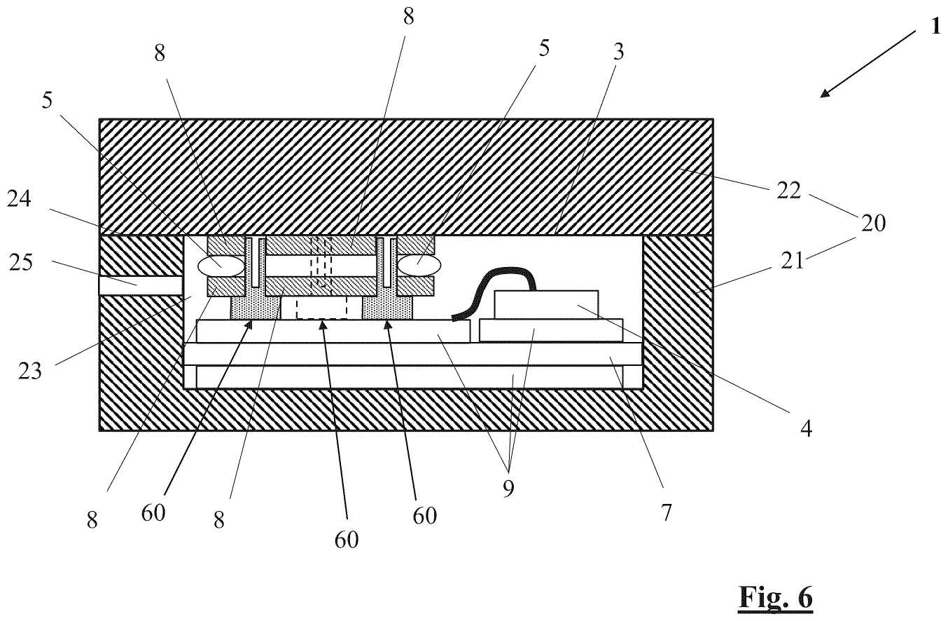

With FIG. 6, a further possibility for implementing the idea of the invention is illustrated, in which two washers 8 are configured as a kind of perforated plates having an equal number of holes to the number of sockets 60 which should be guided free of molding material to the outside of the power module 1 or should be exposed to the outside of the power module 1. In between the two washers 8 a sealing ring 5 is sandwiched, which is elastically deformed when the encapsulation mold 20 is closed. Here the sealing ring can be shaped like an O-Ring comprising a circular, oval, or rectangular form which may copy the external form of the socket shank 62.

Further, the upper washer 8 is not necessarily a perforated plate, since also can have, e.g., an elongated hole through which more than one socket shank 62 can pass. According to the invention the entrance of molding material in an area between two socket shanks 62 has to be avoided. This is achieved as shown in the embodiment of FIG. 6 already by pressing the lower washer 8 onto the socket base 61 by means of elastically deforming the sealing ring 5. As detectable by a person skilled in the relevant art without more, the sealing ring 5 can also be a kind of a disc elastically deformable for being able to transmit a sealing force in the longitudinal direction of the socket shank axis. For a person skilled in the relevant art, it is easily imaginable further that the two washers 8 together with the sealing ring 5 sandwiched therebetween could receive/surround more than two sockets 60 respectively their socket shanks 62 as indicated in FIG. 6 by the socket 60 in depicted dotted lines.

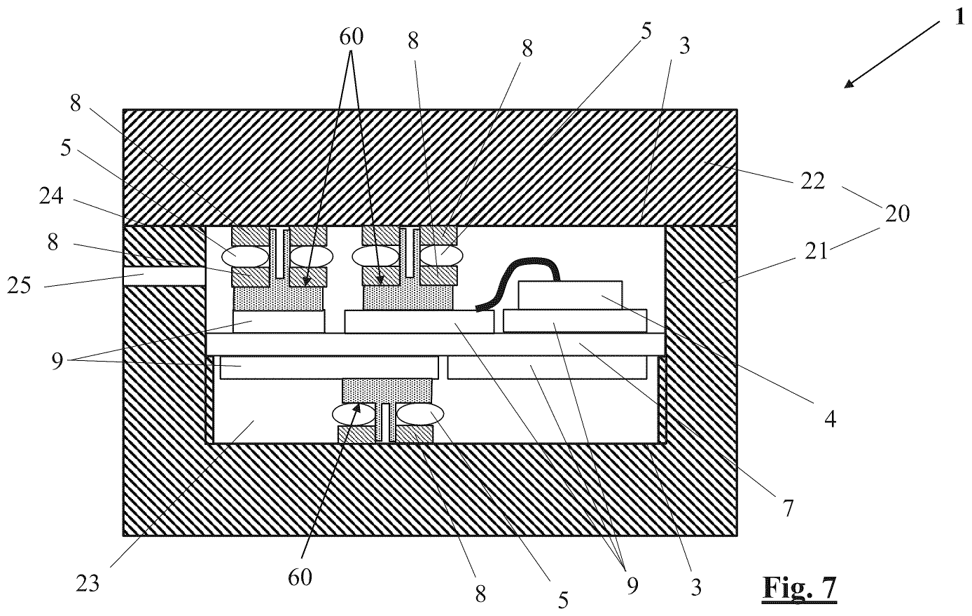

FIG. 7 shows a further embodiment for a power module 1 according to the invention with sockets 60 protruding perpendicular on either side of the substrate 7, i.e. on the upper side as well as on the lower side as depicted with FIG. 7. Here, it has to be considered that, if the sockets 60 protrude the parting planes 24, the one or more sockets 60 which are designed to be accessible, flush or project out of the cured encapsulation material with their socket shank ends 65 require a corresponding recess in the lower mold half 21. However, here, the sockets 60 are designed to not protrude the parting plane 24 and, hence, recesses in the molding die are not required. Further it has to be considered that the non-encapsulated power module 1 has to be pushed downward in order to compress elastically the sealing ring 5 received on the downward facing socket 60. For this a plurality of support ribs may be arranged in the lower mold half 21 of the encapsulation mold 20 to limit the deformation of the sealing ring 5 and to prevent damaging the substrate 7 and the components thereon. The downwards movement of the substrate 7 with the attached components may be done similar to the before mentioned embodiments during placing the upper mold half 22 on the parting plane 24, therewith deforming all sealing rings 5 at the same time. Naturally this is only one of a plurality of possible solutions being in the range of the knowledge of a person skilled in the relevant art. The embodiment of FIG. 7 merely aims to show that the invention is not limited to provide power modules 1 and their method for manufacturing according to the invention having one or more socket shank ends 65 projecting on only one side perpendicular to the substrate 7, since showing that the inventive arrangement of an elastically deformable sealing ring 5 and at least one washer 8 received on the respective socket shank 62 is applicable also to embodiments of power modules 1 having more than one socket shank end 62, and independent whether the socket shank end 65 is exposed to the outside of the power module 1 on only one side or on two opposite sides, e.g. the top side and the bottom side.

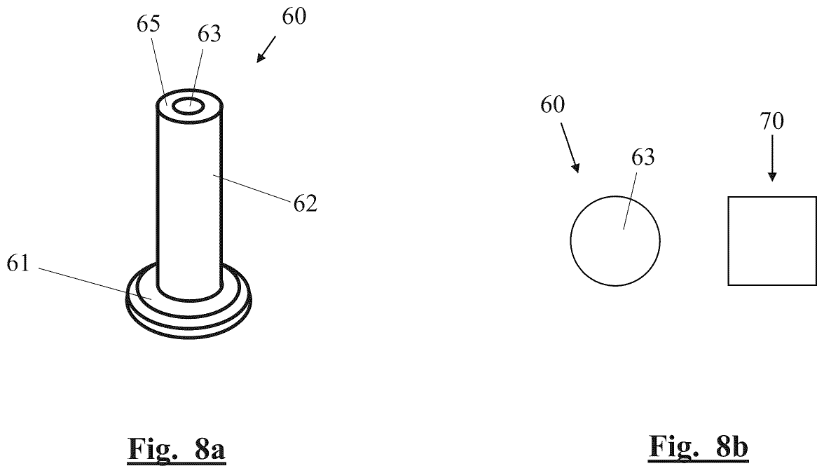

In FIG. 8a a socket 60 is illustrated as an example representing a plurality of sockets which can be used in the implementation of the invention. FIG. 8a shows the socket 60 being rotationally symmetric with respect to the socket shank axis 64 and showing a round cross section. The round socket base 61 is preferably apt to be welded, e.g. by ultrasonic or laser, to the bonded or conductive layer 9 on a substrate 7. The geometric forms of FIG. 8b are examples for cross sections of the hollow shape 63 and the contact pin 70. The left form is an example for a circular cross section of the hollow space 63, and the right form is an example for a rectangular cross section of the contact pin 70. If the contact pin 70 having the rectangular shape is inserted into the hollow space 63 having the circular shape in order to provide an electrical connection to the outside of the power module 1, these two components are press-fitted due to the different shapes. Of course, a person skilled in the relevant art will set a shape of the socket 60 and the shapes of the hollow space 63 and the contact 70 in accordance with the respective application and will therefore provide an appropriate configuration.

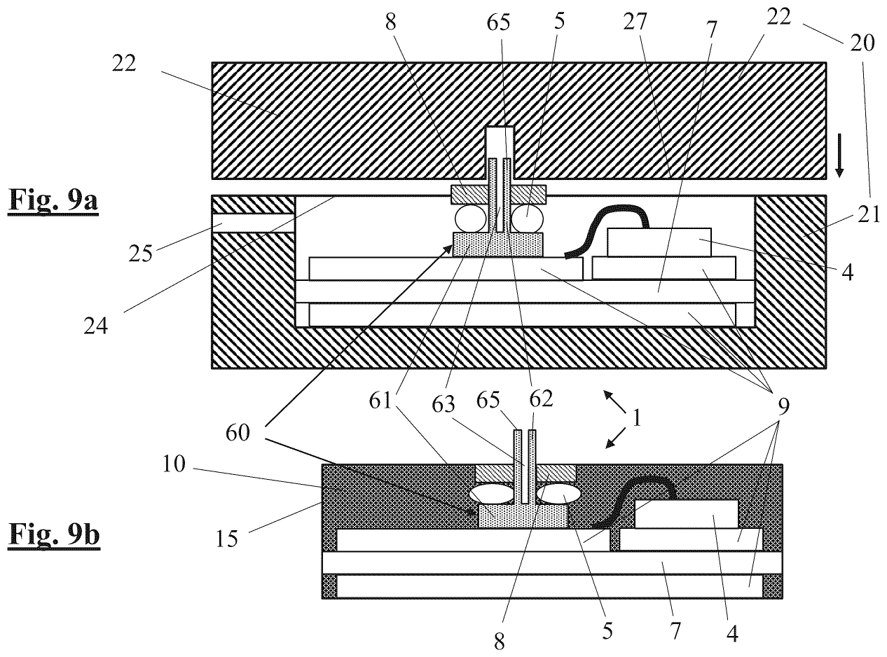

FIG. 9a illustrates an embodiment of the present invention in which the socket 60 protrudes the parting plane 24. As can be seen in FIG. 9, the upper mold half includes the recess which has been already mentioned above. The socket 60 which protrudes the parting plane 24 is received in the recess so that the socket 60 is not damaged when the upper mold half 22 is put on the lower mold half 21. FIG. 9b illustrates the power module 1 of FIG. 9a after the molding process having the casing 15 and the protruding socket 60 with the hollow space 63.

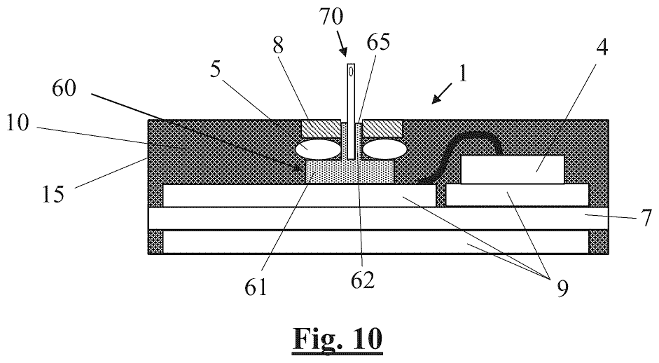

FIG. 10 illustrates a power module 1 comprising the socket 60 in which the contact pin 70 is inserted, e.g. by press-fitting. The contact pin 70 is an electrical pin wherein further electrical components, interconnects, wires, or connectors can be connected to the contact pin 70 so that an electrical connection is provided to the inside of the power module 1. The contact pin 70 is adapted to the socket 60—or vice versa—and in particular to the hollow space 63 of the socket 60 to form a safe and stable connection. However, it is also possible to provide a detachable connection, e.g., using a threaded hole as the hollow space 63 and a screw thread as the outer circumference of the contact pin 70.

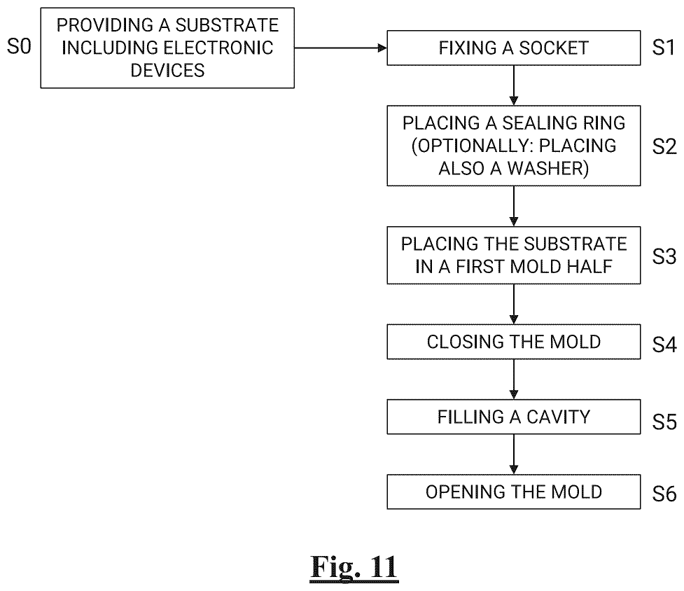

FIG. 11 illustrates a method and the respective method steps for manufacturing the power module 1. In step S0, the substrate 7 is provided wherein the substrate includes electronic devices such as the conductive layer 9 and the semiconductor 4 (or at least one semiconductor 4). The conductive layer 9 and the semiconductor 4 are placed on the substrate 7 and are fixed on the substrate 7.

In step S1, the socket 60 (or at least one socket 60) including the socket base 61, the socket shank 62, and the hollow space 63 is fixed on the conductive layer 9. The socket 60 is fixed such that the socket shank 62 extends perpendicularly to the substrate 7.

In step S2, the sealing ring 5 is placed over the socket shank 62 such that the sealing ring 5 rests on the socket base 61. Optionally, at least one washer 8 can be additionally placed on the socket shank 62 as explained with some embodiments. It is noted that the height of the sealing ring 5 and/or the washers 8 are set so that a stack formed by the sealing ring 5 and the washers 8 placed over the socket shank 62 slightly crosses or protrudes the parting plane 24 so that an axial force can be applied by closing the mold 20 (see step S4).

In step S3, the substrate 7 including the electronic devices and the socket 60 is placed in the first mold half 21. This is the first step for the encapsulation or molding process.

In step S4, the mold 20 is closed to form a cavity 23. The first mold half 21 is closed in the upright direction 11 parallel to the socket shank 62 by means of the second mold half 61. The sealing ring 5 is elastically deformed by pressing it onto the socket base 61 by means of the second mold half 22 (due to the crossing or protruding of the parting plane 24 by the sealing ring 5 or the washer 8) such that the second mold half 22 closes the hollow space 63 of the socket 60, wherein the sealing ring 5 seals the socket shank 62 against entrance of molding material 10 into the hollow space 63. The cavity limiting surface 27 is the surface which presses the sealing ring 5 and/or the washers 8 towards the socket base 61 and the sealing of the socket shank end 65 and the hollows space 63 is ensured by the pressing force between the cavity limiting surface 27 and the sealing ring 5 and/or the washers 8.

In step S5, the cavity 23 formed in the mold 20 is filled with encapsulation or molding material 10. The molding material 10 can be, e.g. an appropriate resin having insulating properties.

In step S6, after curing of the molding material 10, the mold 20 is opened so that the power module 1 can be removed from the mold 20. After the curing process, the molding material 10 forms the casing 15 of the power module 1 which can fully or partially encapsulate the substrate 7, the electronic devices and the socket 60. However, the hollow space 63 and at least a part or an end surface of the socket shank 62 (the socket shank end 65) are exposed to the outside of the power module 1.

Therefore, providing the socket 60 and the method according to the invention improves the ease of manufacturing of the power module 1, ensures reliability of the electrical connections, facilitates flexibility of the circuit configuration, and reduces manufacturing costs.

From the above disclosure and accompanying Figs. and claims, it will be appreciated that the power module according to the invention and the method for manufacturing such a power module offers many possibilities and advantages over the prior art. It will be appreciated further by a person skilled in the relevant art that further modifications and changes known in the art could be made to a power module according to the invention without parting from the spirit of this invention. Therefore, all these modifications and changes are within the scope of the claims and covered by them. It should be further understood that the examples and embodiments described above are for illustrative purposes only and that various modifications, changes, or combinations of embodiments in the light thereof, which will be suggested to a person skilled in the relevant art, are included in the spirit and purview of this application

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A semiconductor power module comprising:
one or more semiconductors placed on a substrate having a conductive layer;
a casing made of molding material encapsulating at least the substrate and the semiconductor;
at least one socket with a socket base mounted on the substrate and configured for receiving and holding a pin connector in a basically upright position perpendicular to the substrate by means of a hollow space in the socket shank defining the upright direction,
at least one sealing ring arranged around the socket shank and resting on the socket base; wherein the sealing ring is fixedly held in an elastically deformed state in the upright direction against the socket base by the molding material and seals the socket shank against entrance of molding material into the hollow space during the molding step of the casing such that the hollow space provides for an opening on the outside surface of the casing.

2. The semiconductor power module according to claim 1, wherein the socket shank and/or the hollow space shows a circular, oval, or rectangular cross section.

3. The semiconductor power module according to claim 1, wherein the sealing ring shows a circular, oval, or rectangular form copying the external form of the socket shank, and wherein the cross section of the sealing ring is circular, oval, rectangular or of any other shape.

4. The semiconductor power module according to claim 1, wherein the sealing ring is pressed against the socket base into an elastically deformed state in the upright direction by means of a washer fixedly hold around the socket shank by the molding material of the casing.

5. The semiconductor power module according to claim 4, wherein the washer shows a circular, oval, or rectangular circumferential form, and a basically rectangular cross section.

6. The semiconductor power module according to claim 4, wherein the sealing ring is sandwiched between two washers one of them resting on the socket base.

7. The semiconductor power module according to claim 4, wherein at least one washer or both washers are made of metal, plastic, reinforced plastic, ceramic or elastic material.

8. The semiconductor power module according to claim 1, wherein the sealing ring is made of an elastomeric or silicone material.

9. The semiconductor power module according to claim 1, wherein the socket base is fixed to the substrate by means of ultrasonic welding, laser welding, soldering, bonding, sintering or press-fit.

10. The semiconductor power module according to claim 1, wherein two or more sockets shanks are fixed next to each other on the substrate, wherein one washer rests on the at least one socket base, and one sealing ring is held elastically deformed in upright direction by a second washer in a sandwiched manner, wherein each of the washers and the sealing ring surround all socket shanks.

11. The semiconductor power module according to claim 1, wherein the hollow space is configured hold and receive the pin connector which is a contact pin of the press-fit pin type of construction so that the contact pin can be inserted and fixed in the hollow space of socket.

12. The semiconductor power module according to claim 1, wherein at least a second socket with at least one sealing ring and one washer received thereon is arranged in an analogous manner in a semiconductor power module according to any of the previous claims, however facing with its hollow space to the opposite side of the substrate.

13. A method for manufacturing a semiconductor power module having one or more semiconductors placed on a substrate having a conductive layer, wherein the substrate and the semiconductors are covered at least partially by a casing formed of a molding material, wherein at least one opening in the casing is provided for electrically contacting the conductive layer, the method comprising the steps of:
a) providing (S0) a substrate having a conductive layer and one or more semiconductors placed on it,
b) fixing (S1) on the conductive layer at least one socket with a socket base such that a socket shank extends perpendicularly to the substrate,
c) placing (S2) a sealing ring over the socket shank such that the sealing ring rests on the socket base,
d) placing (S3) the substrate with the socket and the sealing ring in a first mold half,
e) closing (S4) the first mold half in a upright direction parallel to the socket shank by means of a second mold half, thereby elastically deforming the sealing ring by pressing it onto the socket base by means of the second mold half such that the second mold half closes an hollow space of the socket, wherein the sealing ring seals the socket shank against entrance of molding material into the hollow space,
f) filling (S5) a cavity of the mold with molding material,
g) opening (S6) the mold after curing of the molding material, and
h) removing the semiconductor power module from the mold.
